(19) United States
(12) Patent Application Publication
(10) Pub. No.: US 2013/0334943 A1
(43) Pub. Date: Dec. 19, 2013

(54) HOLDER FOR PORTABLE ELECTRONIC DEVICE

(71) Applicants: HON HAI PRECISION INDUSTRY CO., LTD., New Taipei (TW); HONG FU JIN PRECISION INDUSTRY (ShenZhen) CO.,LTD., Shenzhen (CN)

(72) Inventor: QIANG CHEN, Shenzhen (CN)

(73) Assignee: HON HAI PRECISION INDUSTRY CO., LTD., New Taipei (TW)

(21) Appl. No.: 13/915,782

(22) Filed: Jun. 12, 2013

(30) Foreign Application Priority Data
Jun. 15, 2012 (CN) 2012101979053

(51) Int. Cl. H05K 5/03; A44B 18/00

(52) U.S. Cl. CPC H05K 5/03; A44B 18/00
USPC 312/237; 312/223.1; 24/442; 206/37

(57) ABSTRACT

A foldable holder includes a base, a main plate, a top plate and two side plates. The main plate is connected to the base. The top plate is connected to the main plate opposite to the base. The two side plates are connected to opposite sides of the main plate. The side plates are perpendicular to the main plate and the base. The top plate is perpendicular to the main plate and the two side plates, the main plate, the top plate and the two side plates cooperatively form a three-dimensional structure for obstructing light rays.

### BACKGROUND

1. Technical Field

This disclosure relates to cases for portable electronic devices, particularly, to a holder for obstructing light rays when portable electronic devices are used in an outdoor environment.

Portable electronic devices are often used to read an eBook or to watch a video. However, when the portable electronic devices are used in an outdoor environment, intensive light will directly shine the screen of the portable electronic devices so that users cannot clearly see the content of the screen.

Therefore, there is room for improvement within the art.

### BRIEF DESCRIPTION OF THE DRAWINGS

Many aspects of the holder can be better understood with reference to the following drawings. The components in the drawings are not necessarily drawn to scale, the emphasis instead being placed upon clearly illustrating the principles of the holder.

FIG. 1 is a schematic view of an unfolded holder as disclosed according to a first exemplary embodiment.

FIG. 2 is a schematic view of the folded holder shown in FIG. 1 in a first configuration for the purpose of obstructing light rays for viewing the electronic device.

FIG. 3 is a schematic view of the folded holder shown in FIG. 1 in a second configuration for covering the electronic device.

FIG. 4 is a schematic view of an unfolded holder as disclosed according to a second exemplary embodiment.

FIG. 5 is a schematic view of the folded holder shown in FIG. 4 in a first configuration for the purpose of obstructing light rays for viewing the electronic device.

FIG. 6 is a schematic view of the folded holder shown in FIG. 4 in a second configuration for covering the electronic device.

FIG. 7 is a schematic view of an unfolded holder as disclosed according to a third exemplary embodiment.

FIG. 8 is a schematic view of the folded holder shown in FIG. 7 in a first configuration for the purpose of obstructing light rays for viewing the electronic device.

FIG. 9 is a schematic view of the folded holder shown in FIG. 7 in a second configuration for covering the electronic device.

### DETAILED DESCRIPTION

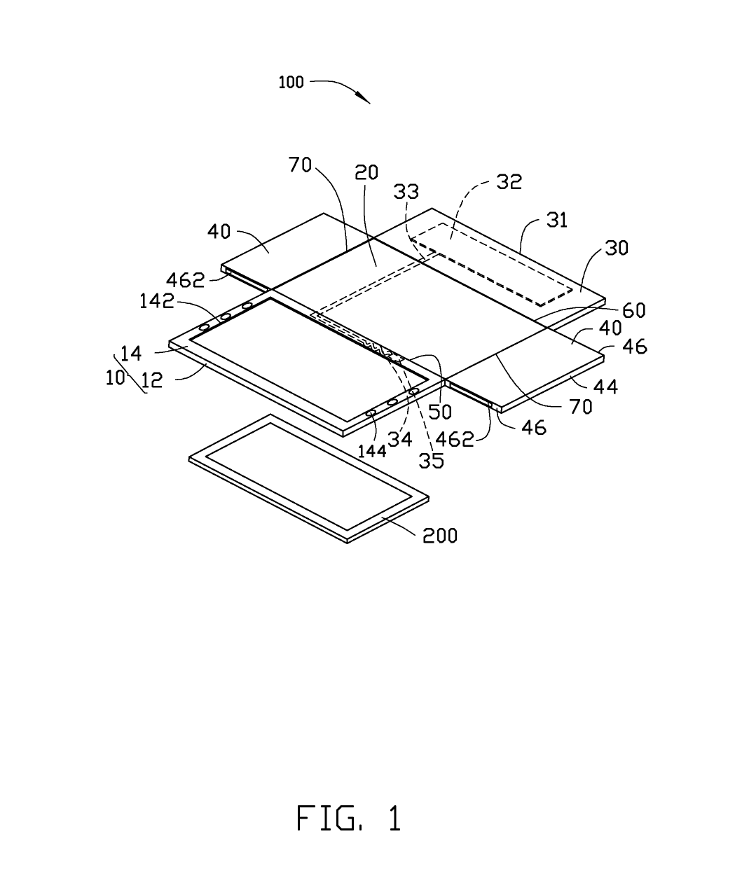

FIG. 1 shows an unfolded holder 100 used for receiving a portable electronic device 200 with flat-panel shaped structures such as a tablet computer, liquid crystal display television (LCD-TV), etc. In this exemplary embodiment, the portable electronic device 200 is a tablet computer.

The holder 100 comprises a base 10, a main plate 20 foldable relative to the base 10, a top plate 30, and two side plates 40. The top plate 30 and the side plates 40 are foldable relative to the main plate 20. The main plate 20 is connected to the base 10, and the top plate 30 is connected to the main plate 20 opposite to the base 10. The two side plates 40 are connected to opposite sides of the main plate 20. In this exemplary embodiment, a flexible skin may be covered on the base 10, the main plate 20, the top plate 30 and the two side plates 40 for connecting the base 10, the main plate 20, the top plate 30 and the two side plates 40 together. The skin is flexible and made of fibrous material such as flannelette. The base 10, the main plate 20, the top plate 30 and the side plates 40 can be made of plastic materials such as polycarbonate. The base 10, the main plate 20, the top plate 30 and the side plates 40 are rigid and cannot be folded themselves. However, the portion between the base 10 and the main plate 20, the portions between the main plate 20 and the top plate 30 and between the side plates and the main plate 20 can be folded due to the flexible ability of the skin. Thus, a first foldable area 50 is formed between the main plate 20 and the base 10. A second foldable area 60 is formed between the top plate 30 and the main plate 20. A third foldable area 70 is formed between one side plate 40 and one side of the main plate 20.

The base 10 has a main body 12 and a cover sheet 14 surrounding the main body 12. A receiving space is defined between the main body 12 and the cover sheet 14 for receiving the portable electronic device 200. The cover sheet 14 has an opening 142 allowing the portable electronic device 200 to be inserted into the receiving space. The cover sheet 14 has at least one hole 144 for allowing external devices to be electronically connected to the portable electronic device 200 received in the holder 100. In this exemplary embodiment, the main body 12 is made of plastic. The cover sheet 14 is made of fibrous material such as flannelette, and is formed by one part of the skin. Understandable, the main body 12 and the cover sheet 14 are made of fibrous material. When the portable electronic device 200 is received in the receiving space, the main body 12 and the cover sheet 14 can be kept in a configuration conforming the shape of the portable electronic device 200.

The main plate 20 is rectangular and has the same size as the base 10. The main plate 20 is folded along the first foldable area 50. The top plate 30 is folded relative to the main plate 20 along the second foldable area 60. The top plate 30 has a free end 31. A fabric hook-and-loop fastener 312 is formed on the top plate 30. After the main plate 20 is folded relative to the base 10 along the first foldable area 50, the top plate 30 is folded along the second foldable area 60 to be positioned under the base 10. The fabric hook-and-loop fastener 312 is configured for being secured to a back of the base 10. Each side plate 40 is folded relative to one side of the main plate 20 along one of the third foldable areas 70. Each side plate 40 has an end surface 44 and two opposite side surfaces 46. Each side surface 46 has a fabric hook-and-loop fastener 462.

An outer surface of the top plate 30 has a solar energy panel 32. The solar energy panel 32 can absorb and storage solar energy for charging the portable electronic device 200. In this exemplary embodiment, the solar energy panel 32 is made of five groups of amorphous silicon solar battery in series for providing a direction current of 5 voltage. A wire 33 is connected to the solar energy panel 32 and has a charging plug 35 extending into the cover sheet 14. The wire 33 has a coiled portion 34 for allowing the wire 33 to have an extended length according to need. When the holder 100 is unfolded, the base 10, the main plate 20, the top plate 30 and the two side plates 40 are coplanar.

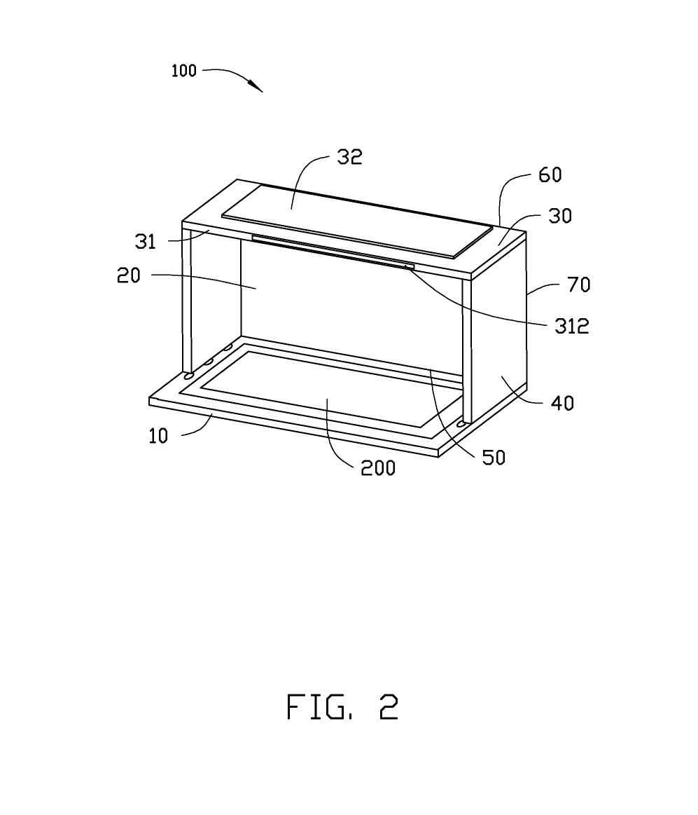

In use, referring to FIG. 2, in an outdoor environment, the main plate 20 is folded toward the base 10 along the first foldable area 50 until the main plate 20 is perpendicular to the base 10. Then, the side plates 40 are folded relative to the main plate 20 along the third foldable areas 70 until the side plates 40 are positioned on the cover sheet 14. One of the side surfaces 46 of each side plates 40 is secured on the cover sheet 14 via the corresponding fabric hook-and loop fasteners 462. Finally, the top plate 30 is folded toward the side plates 40 along the second foldable area 60 and is positioned on the side surfaces 46 of the side plates 40. The side plates 40 are perpendicular to the main plate 20 and the base 10. The top plate 30 is perpendicular to the main plate 20 and the two side plates 40. Thus, the main plate 20, the top plate 30, and the two side plates 40 cooperatively form a three-dimensional structure. The three-dimensional structure may obstruct light rays for more clearly seeing the screen of the portable electronic device.

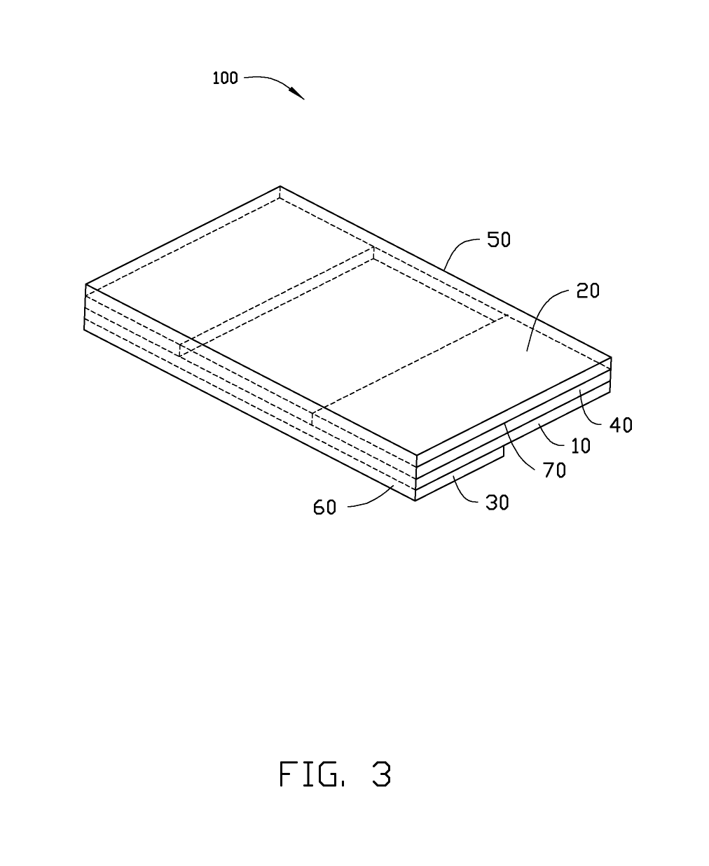

FIG. 3 shows that when the portable electronic device 200 is not being used, the two side plates 40 may be folded toward each other and can be positioned on the main plate 20. The main plate 20 is folded toward the base 10 along the first foldable area 50. The top plate 30 is folded toward the main plate 20 and is positioned under the base 10. Since the main body 12 is made of fibrous material, the fabric hook-and-loop fastener 312 of the free end 31 can be attached to the base 10. The base 10, the main plate 20, the top plate 30, and the two side plates 40 are folded together to form a stacked configuration. Thus, the portable electronic device 200 is protected in the holder 100.

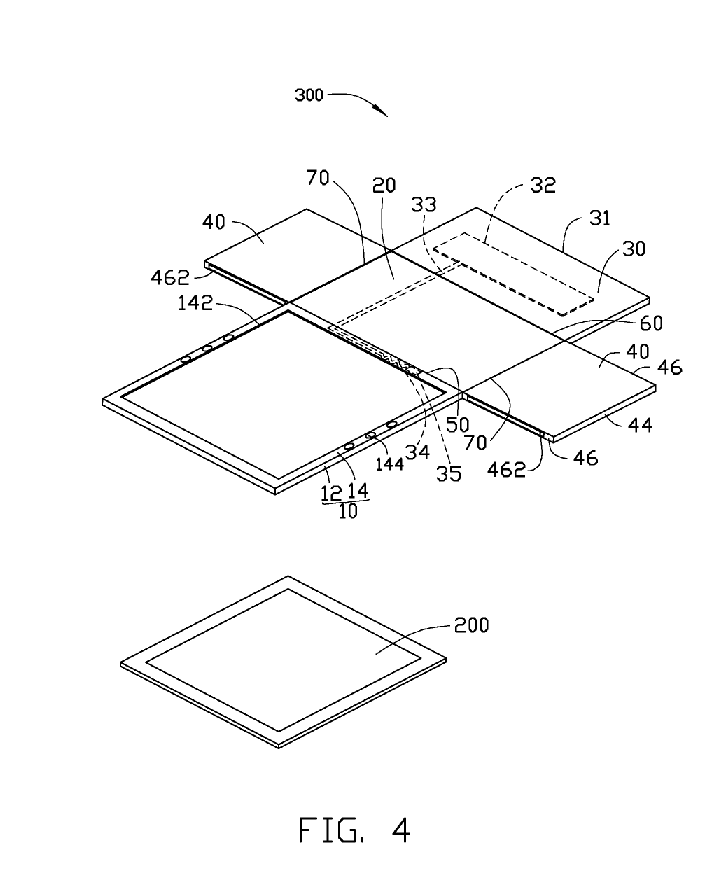

In a second exemplary embodiment, FIG. 4 shows that the holder 300 is similar to the holder 100 of the first exemplary embodiment. The distinguishing difference is that the holder 300 comprises a different size main plate 20. In this exemplary embodiment, the size of the top plate 30 and the main plate 20 is substantially equal to the size of the base 10. Thus, the main plate 20 and the top plate 30 are folded together along the first foldable area 50, the free end 31 faces one end of the base 10.

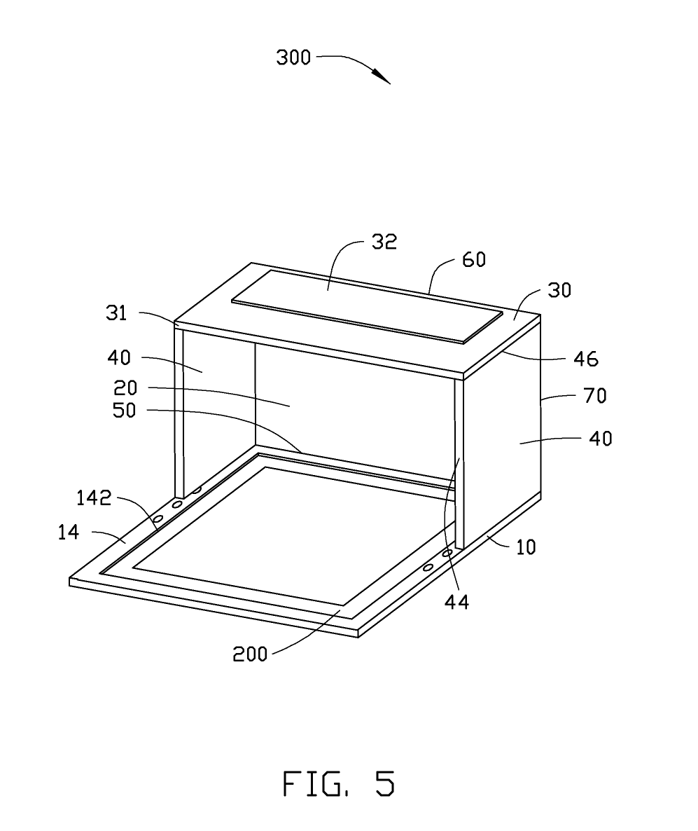

In use, referring to FIG. 5, in an outdoor environment, the main plate 20 is folded toward the base 10 along the first foldable area 50 until the main plate 20 is perpendicular to the base 10. Then, the side plates 40 are folded relative to the main plate 20 along the third foldable areas 70 until the side plates 40 are positioned on the cover sheet 14. One of the side surfaces 46 of each side plates 40 is secured on the cover sheet 14 via the corresponding fabric hook-and loop fasteners 462. Finally, the top plate 30 is folded toward the side plates 40 along the second foldable area 60 and is positioned on the side surfaces 46 of the side plates 40. The side plates 40 are perpendicular to the main plate 20 and the base 10. The top plate 30 is perpendicular to the main plate 20 and the two side plates 40. Thus, the main plate 20, the top plate 30, and the two side plates 40 cooperatively form a three-dimensional structure.

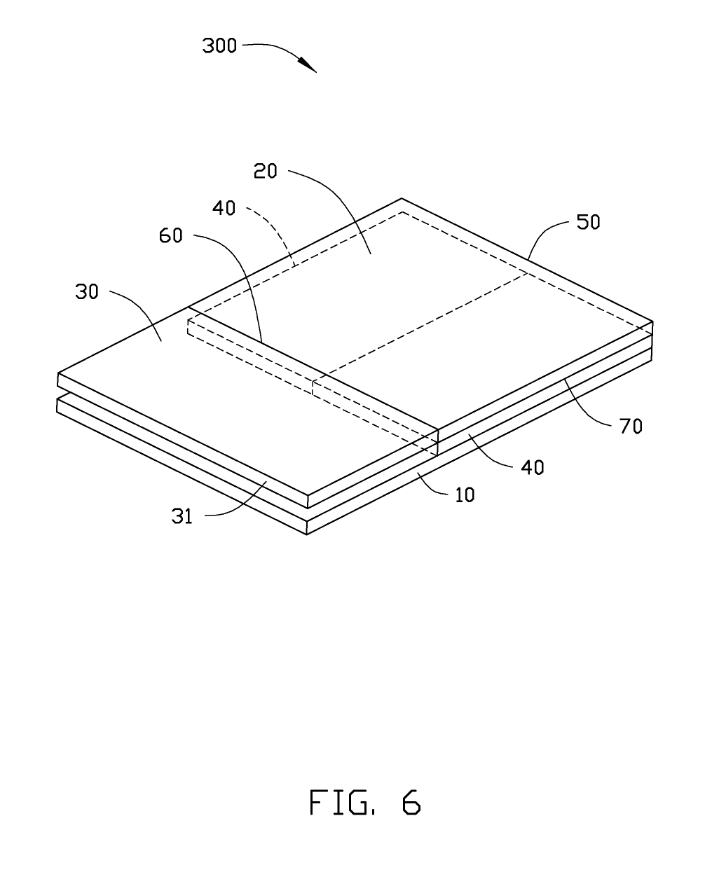

FIG. 6 shows that when the portable electronic device 200 is not being used, the two side plates 40 may be folded toward each other and are positioned on the main plate 20. The main plate 20 and the top plate 30 are together folded toward the base 10 along the first foldable area 50. The base 10, the main plate 20, the top plate 30, and the two side plates 40 are folded together to form a stacked configuration. Thus, the portable electronic device 200 is protected in the holder 100. Understandably, the free end 31 of the top plate 30 may has a clasp for easy latching of the base 10.

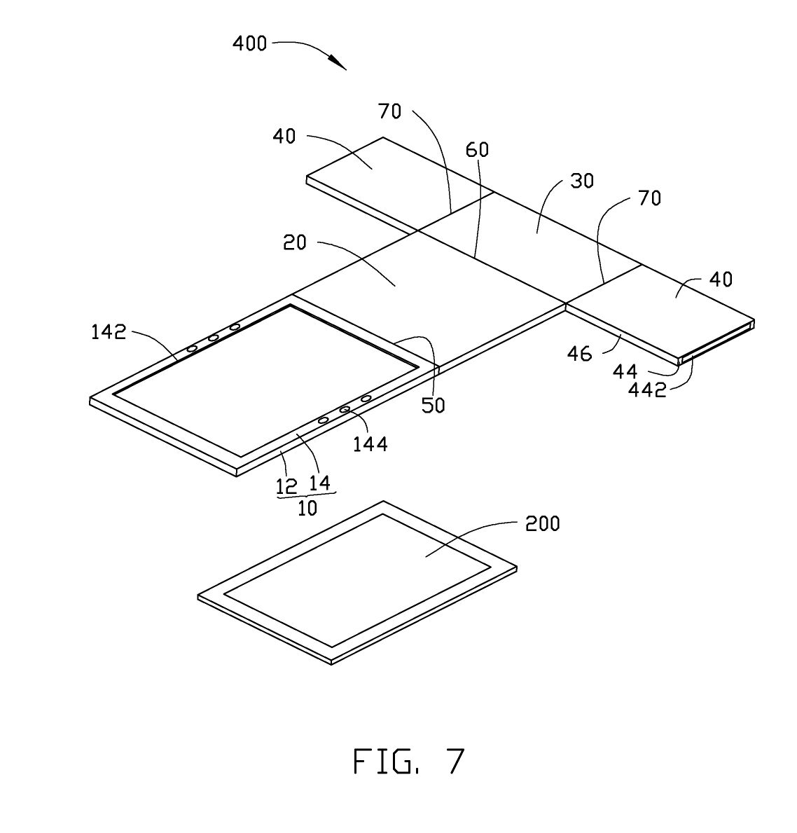

In a third exemplary embodiment, FIG. 7 shows that the holder 400 comprises a top plate 30, two side plates 40. The two side plates 40 are connected to opposite sides of the top plate 30 by two third foldable areas 70. Each side plate 40 has an end surface 44 and two opposite side surfaces 46. The end surface 44 of each side plate 40 has a fabric hook-and-loop fastener 442.

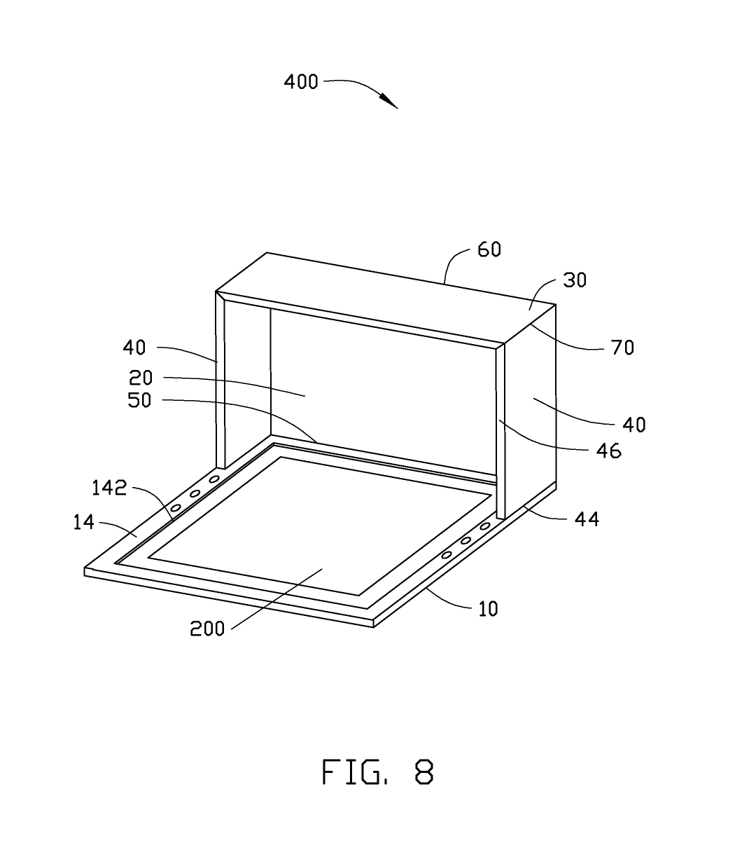

In use, referring to FIG. 8, in an outdoor environment, the main plate 20 is folded toward the base 10 along the first foldable area 50 until the main plate 20 is perpendicular to the base 10. Then, the top plate 30 is folded relative to the main plate 20 along the second foldable area 60. The side plates 40 are folded relative to the top plate 30 along the third foldable areas 70 and are positioned on the cover sheet 14. The end surface 44 of each side plate 40 is secured on the cover sheet 14 via the corresponding fabric hook-and loop fasteners 442. The side plates 40 are perpendicular to the main plate 20 and the base 10. The top plate 30 is perpendicular to the main plate 20 and the two side plates 40. Thus, the main plate 20, the top plate 30 and the two side plates 40 cooperatively form a three-dimensional structure for obstructing light rays.

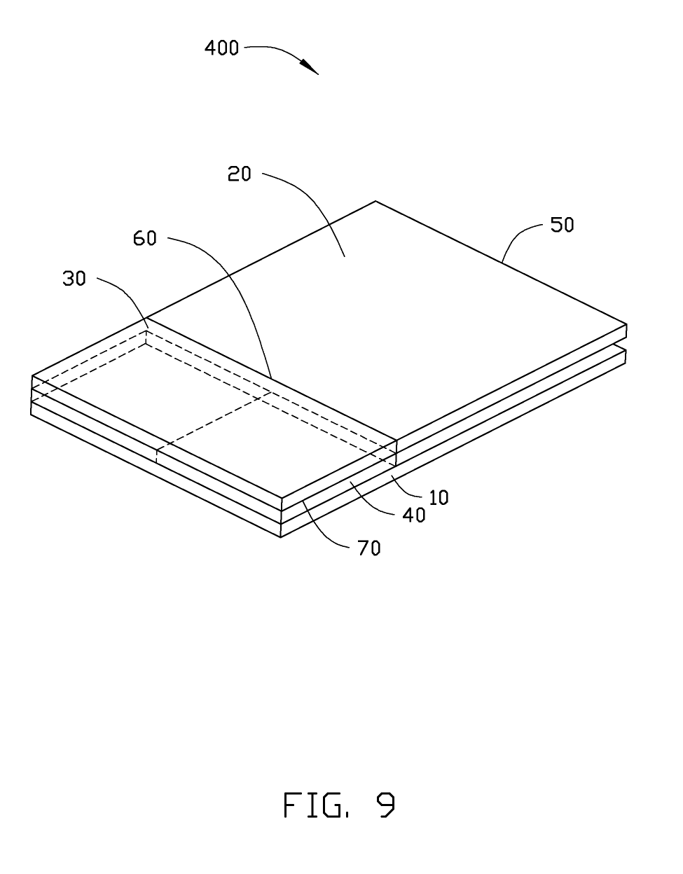

FIG. 9 shows that when the portable electronic device 200 is not being used, the two side plates 40 may be folded toward each other and are positioned on the top plate 30. The main plate 20 and the top plate 30 are folded toward the base 10 along the first foldable area 50. The base 10, the main plate 20, the top plate 30, and the two side plates 40 are folded together to form a stacked configuration. Thus, the portable electronic device 200 is protected in the holder 400.

It is to be understood that even though numerous characteristics and advantages of the present exemplary embodiments have been set forth in the foregoing description, together with details of structures and functions of various embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A foldable holder for holding a portable electronic device, comprising:
a base;
a main plate connected to the base;
a top plate connected to the main plate opposite to the base; and
two side plates connected to opposite sides of the main plate;
wherein:
when the foldable holder is in a first configuration, the base, the main plate, the top plate and the two side plates are coplanar;
when the holder is in a second configuration, the two side plates are perpendicular to the main plate and the base, the top plate is perpendicular to the main plate and the two side plates, the main plate, the top plate and the two side plates cooperatively form a three-dimensional structure;
when the holder is in a third configuration, the base, the main plate, the top plate and the two side plates are folded together to form a stacked configuration.

2. The foldable holder as claimed in claim 1, wherein the top plate has a solar energy panel, and the solar energy panel is configured to charge the portable electronic device.

3. The foldable holder as claimed in claim 2, wherein the solar energy panel is made of five groups of amorphous silicon solar batteries in series for providing a direction current of 5 voltage.

4. The foldable holder as claimed in claim 3, wherein a wire is connected to the solar energy panel and has a charging plug extending into the base, and the wire has a coiled portion for allowing the wire to have an extended length according to need.

5. The foldable holder as claimed in claim 3, wherein the base, the main plate, the top plate and the two side plates are rectangular.

6. The foldable holder as claimed in claim 1, wherein the main plate is connected to the base by a first foldable area, the top plate is connected to the main plate opposite to the base by a second foldable area, when the holder is in a stacked configuration, the two side plates are folded toward each other and are positioned on the main plate, the main plate is folded along the first foldable area for positioning on the base, and the top plate is folded along the second foldable area and is positioned under the base.

7. The foldable holder as claimed in claim 6, wherein the top plate has a fabric hook-and-loop fastener, the fabric hook-and-loop fastener is attached to the base.

8. The foldable holder as claimed in claim 1, wherein each side plate has an end surface and two opposite side surfaces, each side surface has a fabric hook-and-loop fastener for latching the top plate and the base.

9. A foldable holder for holding a portable electronic device, comprising:
a base;
a main plate connected to the base by a first foldable area;
a top plate connected to the main plate opposite to the base by a second foldable area; and
two side plates connected to opposite sides of the main plate by two third foldable areas;
wherein the main plate is folded along the first foldable area relative to the base, the side plates are folded along the two third foldable areas, the top plate is folded along the second foldable area relative to the main plate, the main plate, the top plate and the two side plates cooperatively form a three-dimensional structure.

10. The foldable holder as claimed in claim 9, wherein the base, the main plate, the top plate and the two side plates are rectangular.

11. The foldable holder as claimed in claim 9, wherein when the holder is in a stacked configuration, the two side plates are folded toward each other and are positioned on the main plate, the main plate is folded along the first foldable area for positioning on the base, and the top plate is folded along the second foldable area and is positioned under the base.

12. The foldable holder as claimed in claim 11, wherein the top plate has a fabric hook-and-loop fastener, the fabric hook-and-loop fastener is attached to the base.

13. The foldable holder as claimed in claim 9, wherein each side plate has an end surface and two opposite side surfaces, each side surface has a fabric hook-and-loop fastener for latching the top plate and the base.

14. The foldable holder as claimed in claim 9, wherein the top plate has a solar energy panel, and the solar energy panel is configured to charge the portable electronic device.

15. The foldable holder as claimed in claim 14, wherein the solar energy panel is made of five groups of amorphous silicon solar battery in series for providing a direction current of 5 voltage.

16. The foldable holder as claimed in claim 15, wherein a wire is connected to the solar energy panel and has a charging plug extending into the base, and the wire has a coiled portion for allowing the wire to have an extended length according to need.
